(19) United States
(12) Patent Application Publication
(10) Pub. No.: US 2010/0252106 A1
(43) Pub. Date: Oct. 7, 2010

(54) ANTI-REFLECTIVE AND LIGHT-TRAPPING SOLAR MODULE PACKAGE STRUCTURE

(75) Inventors: Cheng-Yu Peng, Taoyuan County (TW); Chien-Rong Huang, Hsinchu City (TW); Fang-Yao Yeh, Taoyuan County (TW)

Correspondence Address: J C PATENTS, 4 VENTURE, SUITE 250, IRVINE, CA, 92618, US

(73) Assignee: INDUSTRIAL TECHNOLOGY RESEARCH INSTITUTE, Hsinchu (TW)

(21) Appl. No.: 12/651,201

(22) Filed: Dec. 31, 2009

(30) Foreign Application Priority Data
Apr. 1, 2009 (TW) 98110899

(51) Int. Cl. H01L 31/00

(52) U.S. Cl. 136/259

(57) ABSTRACT

A variety of solar module package structures is obtained by disposing an optical sheet on the top surface of the solar module and/or between the glass plate and the solar cell. Through the optical sheet with surface configurations, anti-reflection and light trapping capability of the solar module package structure is improved and the power output is increased.

### CROSS-REFERENCE TO RELATED APPLICATION

This application claims the priority benefit of Taiwan application serial no. 98110899, filed on Apr. 1, 2009. The entirety of the above-mentioned patent application is hereby incorporated by reference herein and made a part of this specification.

### BACKGROUND OF THE INVENTION

1. Field of the Invention

The present invention relates to a package structure, and more particularly to a solar module package structure of high transmittance and light-trapping capability.

2. Description of Related Art

Solar module (photovoltaic module) package structures are commonly fabricated by sandwiching the solar cell(s) between the front and back plates with encapsulant in-between. Considering the light transmitting path, the typical laminate structure of the solar module package structure (from the front-side to the back-side) can be briefed as: (air)/glass plate/encapsulant/solar cell/encapsulant/back-sheet/(air). However, the solar module package structures often suffer reflective-light losses and their power outputs become considerably lowered. In general, the major sources of reflective-light losses can be categorized as: (1). reflective-light losses at the interface between the air and the glass plate, (2) reflective-light losses at the interface between the solar cell surface and the adhesive, and (3) reflective-light losses at the back-sheet.

So far, various approaches have been proposed through the adjustments of the structural designs or choices of package materials, with the intention of decreasing reflective-light losses and improving the module efficiency. Among them, the fabrication processes of most approaches are complicated and costly. Even if certain approach may satisfy the requirements of high transparency, the fabrications of uniform and large-sized module package structures turn out to be difficult or problematical.

It is desirable to achieve low reflective-light losses and offer high transparency and at the same time.

### SUMMARY OF THE INVENTION

In view of the foregoing, the present invention provides a solar module package structure, which offers high transmittance and highly light-trapping effects. By employing one or more optical sheets or films with surface textures to the solar module package structures, the solar power output or photovoltaic efficiency of the solar module package structures can be enhanced.

The present invention is further directed to a solar module package structure including a back-plate, a glass plate, at least a solar cell, an encapsulant and at least one optical sheet disposed above the solar cell. The light-receiving surface (front-side) of the optical sheet includes surface configurations or surface patterns, and the optical sheet can achieve high front side transmittance and high backside reflection.

The present invention provides a solar module package structure having a back-plate, a glass plate disposed above the back-plate, a solar cell disposed between the glass plate and the back-plate, an encapsulant disposed between the glass plate and the back-plate, and a first optical sheet disposed above the solar cell.

According to embodiments of the present invention, the first optical sheet is disposed in the encapsulant and between the glass plate and the solar cell, and a light receiving surface of the first optical sheet has surface configurations and is a front side surface, while an opposite surface of the first optical sheet facing the solar cell is a backside surface. The first optical sheet has high front side transmittance and high backside reflection.

According to embodiments of the present invention, a second optical sheet is further mounted on the glass plate. The light receiving surface of the second optical sheet has surface configurations and is a front side surface, while an opposite surface of the second optical sheet facing the glass plate is a backside surface. The second optical sheet has high front side transmittance and high backside reflection.

According to embodiments of the present invention, the first optical sheet is mounted on the glass plate and the solar cell, and a light receiving surface of the first optical sheet has surface configurations and is a front side surface, while an opposite surface of the first optical sheet facing the solar cell is a backside surface. The first optical sheet has high front side transmittance and high backside reflection.

Based on the above, at least one or multiple optical sheets with surface configurations are added to the solar module package structure for increasing photovoltaic performance and power output. By using the optical sheet capable of trapping reflective light from the solar cell and back-plate and achieving anti-reflection and high transmittance, the solar module package structure of the present invention has better photovoltaic effectiveness. In addition, the design of solar module package structure of the present invention can employs the commonly used packaging materials and is compatible with the present manufacturing packaging processes.

In order to the make the aforementioned and other objects, features and advantages of the present invention comprehensible, several embodiments accompanied with figures are described in detail below.

### BRIEF DESCRIPTION OF THE DRAWINGS

FIGS. 1A-1B are enlarged, schematic, cross-sectional views showing a portion of an optical sheet according to one embodiment of the present invention.

FIG. 2 illustrates the optical characteristics of the optical sheet.

FIG. 3 is a schematic cross-sectional view of one general, surface-mounted type solar module package structure according to an embodiment of the present invention.

FIG. 4 is a schematic cross-sectional view of one transparent, surface-mounted type solar module package structure according to an embodiment of the present invention.

FIG. 5 is a schematic cross-sectional view of one general, inter-layered type solar module package structure according to an embodiment of the present invention.

FIG. 6 is a schematic cross-sectional view of one transparent, inter-layered type solar module package structure according to an embodiment of the present invention.

FIG. 7 is a schematic cross-sectional view of one general, combinational type solar module package structure according to an embodiment of the present invention.

FIG. 8 is a schematic cross-sectional view of one transparent, combinational type solar module package structure according to an embodiment of the present invention.

FIG. 9 shows schematic views of various designs of the surface textures applicable for the embodiments of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Though the addition of one or more optical sheets or films with surface textures or configurations, the solar module package structure can achieve anti-reflection and afford light-trapping effects.

The package structures or related modifications described in the present invention can be applied for general types or transparent types of solar module package structures. As described hereinafter, the general types of solar module package structures refer to the package structures with back-sheets being opaque or not being fully transparent, while the transparent types of solar module package structures refer to the package structures with transparent back-sheets or glass back-plates. The fabrication methods as described in the present invention are uncomplicated and straightforward, and compatible with the conventionally packaging processes along with the currently used packaging materials. Moreover, photovoltaic efficiencies of the solar module package structures according to the present invention are increased.

At least three major categories of solar module package structures are proposed as follows. (1) Inter-layered type package structure, by inserting the optical sheet between the glass plate and the solar cell(s), so that the solar module package structure can achieve high transmittance at the front side and improve light-trapping of the reflective-light between the backside of the optical sheet/solar cell or the backside of the optical sheet/back-sheet. (2) Surface-mounted type package structure, by adding the optical sheet on the front surface of the glass plate, so that the solar module package structure can achieve anti-reflection and improve light-trapping at the front side. (3) Combinational type package structure, by mounting the optical sheet on the glass plate as well as inserting the optical sheet between the glass plate and the solar cell(s), so as to boost the light-trapping effects of the solar module package structures.

Moreover, even with the addition of the optical sheet(s), the solar module package structures as described herein can maintain high light transmittance over the solar light spectrum.

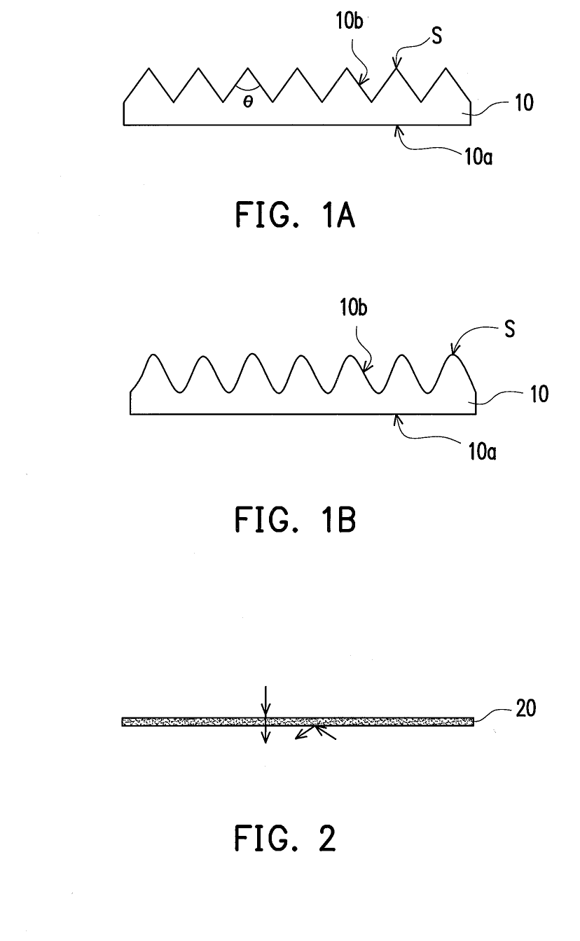

According to the embodiments of this invention, the surface-textured optical sheet or optical film 10 is a mono-layered sheet having a smooth surface 10a and the opposite surface 10b having surface textures (surface configurations) S. The surface textures S are mainly composed of or include three-dimensional geometrical patterns. For example, the geometrical patterns of the surface textures S can be serration structures with parallel trenches and ridges or spines or protrusion structures arranged in arrays. Taking geometrical patterns of the surface textures S being serration structures as examples, the cross-sectional view of the geometrical patterns can be serrations with sharp apexes as shown in FIG. 1A or serrations with curved apexes shown in FIG. 1B. The serrations with sharp apexes as shown in FIG. 1A, for example, have a size ranging from about 10 microns to 2 centimeters, and an angle θ of the sharp apexes ranges from about nearly 0° to 80°. For the serrations with curved apexes (or wave-shaped) shown in FIG. 1B, the curvature of the curved apexes can be obtained by a first order approximation, a second order approximation, a higher order or a polynomial approximation.

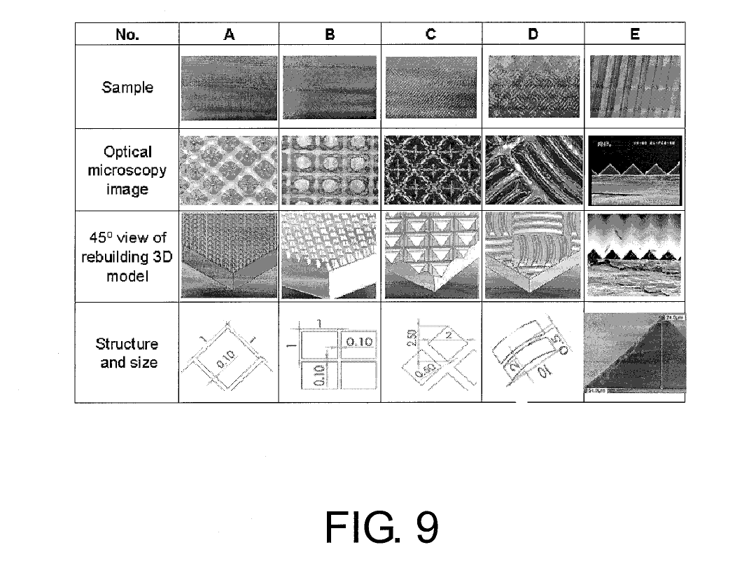

Additionally exemplary designs of the geometrical patterns of the surface textures S are shown in FIG. 9, while various three-dimensional geometrical patterns are shown in sections (A)-(E).

For the description conveniences, the ridged, uneven surface 10b of the optical sheet 10 is referred as the front surface of the optical sheet 10, while the smooth, flat surface 10a is referred as the back surface of the optical sheet 10. For the optical sheet described herein, the phenomenon that the incident light can transmit through the front surface of the optical sheet and the optical sheet (shown as the downward arrows in FIG. 2) is called the front-side transmittance of the optical sheet, while the phenomenon that reflection occurs at the optical sheet (shown as the bent arrows in FIG. 2) is called the backside reflection of the optical sheet. The two opposite surfaces of the optical sheet 20 shown in FIG. 2 are unequal, and only the front surface is designed to have surface configurations. In this case, the optical sheet 20 can satisfy the requirements of high front-side transmittance and high backside reflection. The designs of the surface configurations, including the dimensions, the angle θ or the curvatures, can be adjusted according to the design or material choices of the package structures.

In principle, the index of refraction of (the material of) the optical sheet is larger than that of the air or the encapsulant for achieving total reflection. The mechanism of total reflection makes high backside reflection and better light trapping possible. In addition to high light transmittance, the surface configurations of the optical sheet according to the embodiments of this invention are also designed to achieve total refection at the surface configuration/air interfaces or the surface configuration/encapsulant interfaces for assisting backside reflection.

For the optical sheet, its index of refraction needs to be different from that of surrounding materials for the purposes of total reflection. The surface configurations of the optical sheet not only aid light from the front transmitting through the optical sheet with less reflection but also help reflecting the reflective light reflected from the back-sheet or the solar cell.

For example, when the optical sheet is located between the encapsulant and the solar cell, the index of refraction n of the optical sheet ranges between the index of refraction of the encapsulant (e.g. 1.45) and the index of refraction of the top layer of the solar cell (for example, the index of refraction of silicon nitride is about 2.4), that is, 1.45<n<2.4. For example, when the optical sheet is located between the air and the glass plate, the index of refraction n of the optical sheet ranges between the index of refraction of the air (e.g. 1.0) and the index of refraction of the glass plate (e.g. 1.5), that is, 1.0<n<1.5.

Hence, the index of refraction n of the optical sheet, dependent on its location in-between, should range between the indexes of refraction of the above and below materials. That is, the choice of the material of the optical sheet depends on the materials of the above and below layers. In addition, the thickness of the optical sheet or the design of its surface configurations can also be adjusted according to its location. For example, the angle θ of the surface textures can be changed depending on its location or the neighboring materials, so as to achieve high front-side transmittance and high backside reflection.

By applying the optical sheet(s) to the solar module package structure, the power output of the solar module package structure is increased. The applied optical sheet(s) of the solar module package structure(s) facilitate light trapping of the reflective light reflected from the surface of the solar cell, the reflective light from the back-sheet, and/or the light passing through the intervals of the solar cells, thus enhancing the photovoltaic efficiency of the solar module.

### EXAMPLE 1

### General, Surface-Mounted Type Package Structure

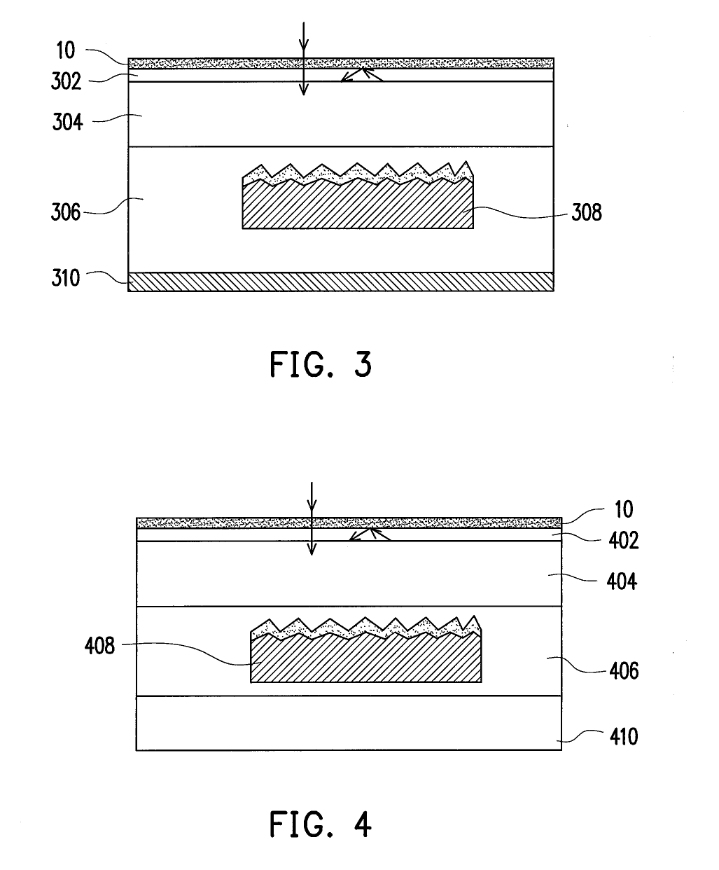

One optical sheet is mounted on the front surface of the general type package structure, as shown in FIG. 3. The new laminate structure is designed as: (optical sheet 10/encapsulant 302/glass plate 304/encapsulant 306/solar cell 308/encapsulant 306/highly reflective back-sheet 310) (from the front to the back). According to the present pressing processes, the above laminate structure is placed into the laminator at 165.0° C. and a vacuum in 10⁻² ton is drawn from the upper and lower chambers for 8 minutes in total. Next, the vacuum of the upper chamber is broken for 8 minutes and the solar module package structure is pressed and sealed. The above laminate structure can be fabricated by employing the pressing processes compatible with the currently used laminator machinery.

For example, the material(s) of the encapsulant 302/306 can be selected from ethylene vinyl acetate (EVA) or polyvinyl butyral (PVB), while the glass plate 304 of the above laminate structure can a film-coated glass plate, a textured glass plate or a flat glass plate. The solar cell 308 may has a silicon nitride anti-reflection layer, and the material of the highly reflective back-sheet 310 can be Tedlar™.

Under STC conditions, A-class flash simulator is used to test the power output of the above laminate structure, when compared with the control group (without the optical sheet 10), the power output(s) of the above laminate structure(s) described in Example 1 is increased. When the surface textures of the optical sheet 10 are serration structures shown in FIG. 1A, the cell maximum power (Pmp) of the above solar module package structure is increased about 2.30%. When the surface textures of the optical sheet 10 are waved structures shown in FIG. 1B, the cell maximum power (Pmp) of the above solar module package structure is increased about 1.87%.

### EXAMPLE 2

### Transparent, Surface-Mounted Type Package Structure

One optical sheet is mounted on the front surface of the transparent type package structure, as shown in FIG. 4. The new laminate structure is designed as: (optical sheet 10/encapsulant 402/glass plate 404/encapsulant 406/solar cell 408/encapsulant 406/glass back plate 410) (from the front to the back). According to the present pressing processes, the above laminate structure is placed into the laminator at 165.0° C. and a vacuum in 10⁻² torr is drawn from the upper and lower chambers for 8 minutes in total. Next, the vacuum of the upper chamber is broken for 8 minutes and the solar module package structure is pressed and sealed. The above laminate structure can be fabricated by employing the pressing processes compatible with the currently used laminator machinery.

For example, the material(s) of the encapsulant 402/406 can be selected from ethylene vinyl acetate (EVA) or polyvinyl butyral (PVB), while the glass plate 404 of the above laminate structure can a film-coated glass plate, a textured glass plate or a flat glass plate. The solar cell 408 may has a silicon nitride anti-reflection layer, for example.

Under STC conditions, A-class flash simulator is used to test the power output of the above laminate structure, when compared with the control group (without the optical sheet 10), the power output(s) of the above laminate structure(s) described in Example 2 is increased. When the surface textures of the optical sheet 10 are serration structures shown in FIG. 1A, the cell maximum power (Pmp) of the above solar module package structure is increased about 3.07%. When the surface textures of the optical sheet 10 are waved structures shown in FIG. 1B, the cell maximum power (Pmp) of the above solar module package structure is increased about 0.52%.

### EXAMPLE 3

### General, Inter-Layered Type Package Structure

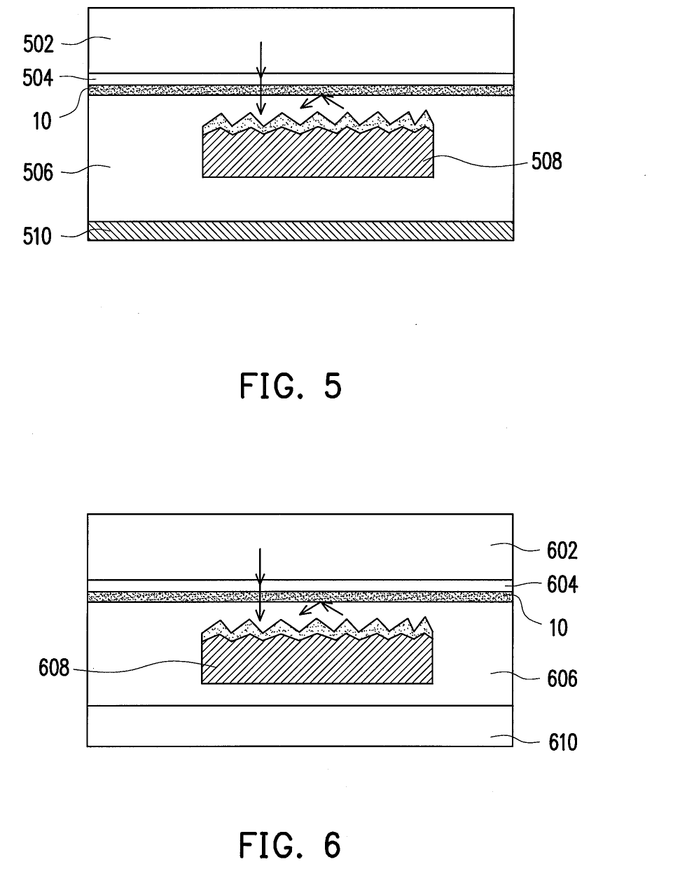

One optical sheet is added between the glass plate and the solar cell of the general type package structure, as shown in FIG. 5. The new laminate structure is designed as: (glass plate 502/encapsulant 504/optical sheet 10/encapsulant 506/solar cell 508/encapsulant 506/highly reflective back-sheet 510) (from the front to the back). According to the present pressing processes, the above laminate structure is placed into the laminator at 165.0° C. and a vacuum in 10⁻² torr is drawn from the upper and lower chambers for 8 minutes in total. Next, the vacuum of the upper chamber is broken for 8 minutes and the solar module package structure is pressed and sealed. The above laminate structure can be fabricated by employing the pressing processes compatible with the currently used laminator machinery.

For example, the material(s) of the encapsulant 504/506 can be selected from ethylene vinyl acetate (EVA) or polyvinyl butyral (PVB), while the glass plate 502 of the above laminate structure can a film-coated glass plate, a textured glass plate or a flat glass plate. The solar cell 508 may has a silicon nitride anti-reflection layer, and the material of the highly reflective back-sheet 510 can be Tedlar™, for example.

Under STC conditions, A-class flash simulator is used to test the power output of the above laminate structure, when compared with the control group (without the optical sheet 10), the power output(s) of the above laminate structure(s) described in Example 3 is increased. When the surface textures of the optical sheet 10 are serration structures shown in FIG. 1A, the cell maximum power (Pmp) of the above solar module package structure is increased about 0.25%. When the surface textures of the optical sheet 10 are waved structures shown in FIG. 1B, the cell maximum power (Pmp) of the above solar module package structure is increased about 1.12%.

### EXAMPLE 4

### Transparent, Inter-Layered Type Package Structure

One optical sheet is added between the glass plate and the solar cell of the transparent type package structure, as shown in FIG. 6. The new laminate structure is designed as: (glass plate 602/encapsulant 604/optical sheet 10/encapsulant 606/solar cell 608/encapsulant 606/glass back plate 610) (from the front to the back). According to the present pressing processes, the above laminate structure is placed into the laminator at 165.0° C. and a vacuum in 10⁻² torr is drawn from the upper and lower chambers for 8 minutes in total. Next, the vacuum of the upper chamber is broken for 8 minutes and the solar module package structure is pressed and sealed. The above laminate structure can be fabricated by employing the pressing processes compatible with the currently used laminator machinery.

For example, the material(s) of the encapsulant 604/606 can be selected from ethylene vinyl acetate (EVA) or polyvinyl butyral (PVB), while the glass plate 602 of the above laminate structure can a film-coated glass plate, a textured glass plate or a flat glass plate. The solar cell 608 may has a silicon nitride anti-reflection layer, for example.

Under STC conditions, A-class flash simulator is used to test the power output of the above laminate structure, when compared with the control group (without the optical sheet 10), the power output(s) of the above laminate structure(s) described in Example 4 is increased. When the surface textures of the optical sheet 10 are serration structures shown in FIG. 1A, the cell maximum power (Pmp) of the above solar module package structure is increased about 0.10%. When the surface textures of the optical sheet 10 are waved structures shown in FIG. 1B, the cell maximum power (Pmp) of the above solar module package structure is increased about 0.86%.

### EXAMPLE 5

### General, Combinational Type Package Structure

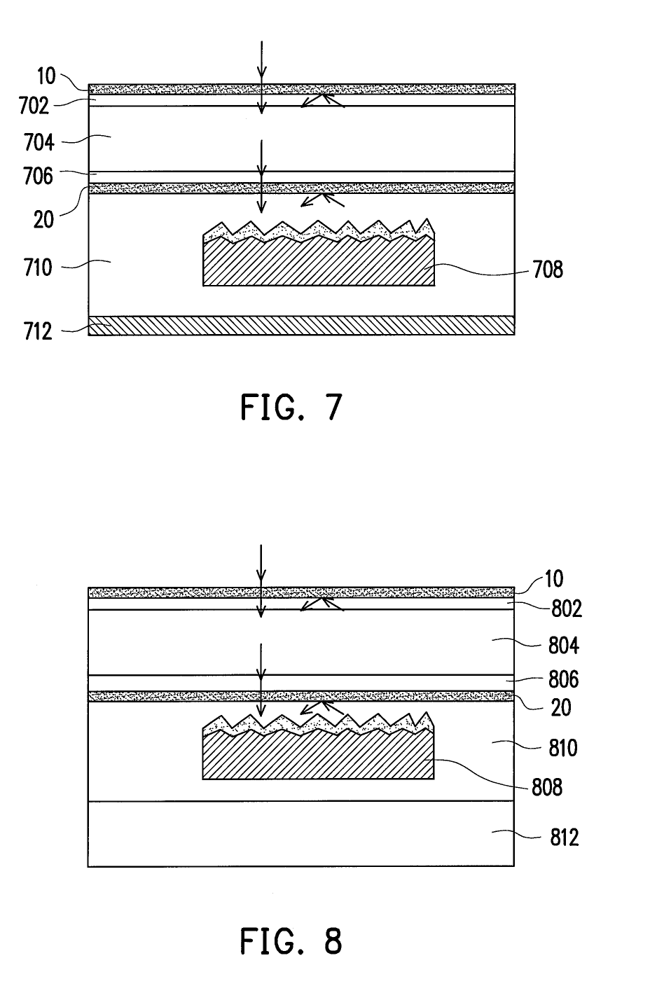

One optical sheet is mounted to the glass plate and another optical sheet is added between the glass plate and the solar cell of the general type package structure, as shown in FIG. 7. The new laminate structure is designed as: (optical sheet 10/encapsulant 702/glass plate 704/encapsulant 706/optical sheet 20/encapsulant 710/solar cell 708/encapsulant 710/highly reflective back-sheet 712) (from the front to the back). According to the present pressing processes, the above laminate structure is placed into the laminator at 165.0° C. and a vacuum in 10⁻² ton is drawn from the upper and lower chambers for 8 minutes in total. Next, the vacuum of the upper chamber is broken for 8 minutes and the solar module package structure is pressed and sealed. The above laminate structure can be fabricated by employing the pressing processes compatible with the currently used laminator machinery.

The optical sheets 10 and 20 may adopt different materials or thickness, and/or have different or the same designs of surface configurations. In this embodiment, the optical sheets 10 and 20 have the same designs of surface configurations.

Under STC conditions, A-class flash simulator is used to test the power output of the above laminate structure, when compared with the control group (without the optical sheets 10/20), the power output(s) of the above laminate structure(s) described in Example 5 is increased. When the surface textures of the optical sheets 10/20 are serration structures shown in FIG. 1A, the cell maximum power (Pmp) of the above solar module package structure is increased about 0.47%.

### EXAMPLE 6

### Transparent, Combinational Type Package Structure

One optical sheet is mounted to the glass plate and another optical sheet is added between the glass plate and the solar cell of the transparent type package structure, as shown in FIG. 8. The new laminate structure is designed as: (optical sheet 10/encapsulant 802/glass plate 804/encapsulant 806/optical sheet 20/encapsulant 810/solar cell 808/encapsulant 810/glass back plate 812) (from the front to the back). According to the present pressing processes, the above laminate structure is placed into the laminator at 165.0° C. and a vacuum in 10⁻² torr is drawn from the upper and lower chambers for 8 minutes in total. Next, the vacuum of the upper chamber is broken for 8 minutes and the solar module package structure is pressed and sealed. The above laminate structure can be fabricated by employing the pressing processes compatible with the currently used laminator machinery.

The optical sheets 10 and 20 may adopt different materials or thickness, and/or have different or the same designs of surface configurations. In this embodiment, the optical sheets 10 and 20 have the same designs of surface configurations.

Under STC conditions, A-class flash simulator is used to test the power output of the above laminate structure, when compared with the control group (without the optical sheets 10/20), the power output(s) of the above laminate structure(s) described in Example 6 is increased. When the surface textures of the optical sheets 10/20 are serration structures shown in FIG. 1A, the cell maximum power (Pmp) of the above solar module package structure is increased about 2.16%.

### EXAMPLE 7

### Arrangements of the Optical Sheet in Different Locations

From the above examples, it is found that serration structures of FIG. 1A or serration structures of FIG. 1B can increase the power outputs of the Inter-layered package structures respectively up to 0.10-0.25% or 0.86-1.12%. Through adjusting the arrangement of the locations of the optical sheet between the glass plate and the solar cell, the resultant differences of the power output is not larger than 0.10%, from the closest location to the glass plate to the closest location to the solar cell surface.

FIG. 9 exemplifies the schematic views of the design of the three-dimensional surface textures, according to the embodiment of this invention. For the optical sheet with surface textures or configurations, it can be considered to be the “textured” optical sheet, from macroscopic views. The structural units shown in sections (A)-(D) are in millimeters (mm), while the structural unit of section (E) is in microns (μm). For section (A) of FIG. 9, the three-dimensional geometric patters are grid and prickle arrays with a dimension, a repetition cycle or a height ranging from 0.1-10 mm, and the material of the optical sheet can be glass, for example. For section (B) of FIG. 9, the three-dimensional geometric patters are flattop pyramid arrays with a dimension, a repetition cycle or a height ranging from 0.1 mm to several millimeters, and the material of the optical sheet can be glass, for example. For section (C) of FIG. 9, the three-dimensional geometric patters are grid and pyramid arrays with a dimension, a repetition cycle or a height ranging from 0.1-10 mm, and the material of the optical sheet can be glass, for example. For section (D) of FIG. 9, the three-dimensional geometric patters are arched spine arrays with a dimension, a repetition cycle or a height ranging from 0.1-100 mm, and the material of the optical sheet can be glass, for example. For section (E) of FIG. 9, the three-dimensional geometric patters are parallel-arranged, revered-V shaped, sloped ridge arrays with a dimension, a repetition cycle or a height ranging from tens microns to several hundred microns, and the material of the optical sheet can be PET, for example.

### EXAMPLE 8

### Comparisons of Package Structures with the Textured Glass Plate or Non-Textured Glass Plate

The control group adopts non-textured glass plate without the optical sheet, while the comparative group adopts textured glass plate without the optical sheet. Under STC conditions, A-class flash simulator is used to test the power outputs of the comparative group and the control group, it is found that the power output of the comparative group, when compared with the control group, is altered about −1.80%-2.49% (i.e. sometimes decreased). However, when comparing the Combinational, transparent type solar module package structures of the above embodiments with the control group, the power output of the above Combinational, transparent type solar module package structure is increased about 0.10%-3.07%. Therefore, when compared with the solar module package structure using the textured glass plate, the solar module package structures utilizing the optical sheets with various designs, as described in the embodiments of this invention, are capable of providing better photovoltaic efficiencies.

In addition, the optical sheets added to the solar module package structures can be easily replaced or repaired, thus solving the soiled or damaged problems during long-term usage.

In summary, at least one or more optical sheets designed with surface textures, which are capable of high front transmittance and trapping reflective lights from the solar cell and the back-sheet, are applied to the solar module package structures, for enhancing photovoltaic efficiency. By doing so, there is no need to replace the commonly used package materials and the manufacturing processes are compatible with the present manufacturing processes.

According to the embodiments of this invention, the optical sheet(s), of glass or plastic materials, with surface textures or configurations can be added or inserted to the existing or modified solar module package structures, for improving the performance of the optical electronic devices. Further, the photovoltaic values of the solar module package structures can be significantly increased.

Accordingly, the designs disclosed in the present invention are applicable for photovoltaic solar module package structures as well as other package structures of optical electronic devices.

Although the present invention has been disclosed above by the embodiments, they are not intended to limit the present invention. Anybody skilled in the art can make some modifications and alteration without departing from the spirit and scope of the present invention. Therefore, the protecting range of the present invention falls in the appended claims.

What is claimed is:

1. A solar module package structure, comprising:
a back-plate;
a glass plate disposed above the back-plate;
a solar cell disposed between the glass plate and the back-plate;
an encapsulant disposed between the glass plate and the back-plate, fixing and encapsulating the solar cell; and
a first optical sheet disposed above the solar cell, wherein the first optical sheet is disposed in the encapsulant and between the glass plate and the solar cell, and a light receiving surface of the first optical sheet has surface configurations and is a front side surface, while an opposite surface of the first optical sheet facing the solar cell is a backside surface, and wherein the first optical sheet has high front side transmittance and high backside reflection.

2. The solar module package structure as claimed in claim 1, further comprising a second optical sheet mounted on the glass plate, wherein a light receiving surface of the second optical sheet has surface configurations and is a front side surface, while an opposite surface of the second optical sheet facing the glass plate is a backside surface, and wherein the second optical sheet has high front side transmittance and high backside reflection.

3. The solar module package structure as claimed in claim 2, wherein an index of refraction of the second optical sheet is larger than that of air and smaller than that of the glass plate.

4. The solar module package structure as claimed in claim 1, wherein an index of refraction of the first optical sheet is larger than that of the encapsulant but smaller than that of the solar cell.

5. The solar module package structure as claimed in claim 1, wherein the surface configurations of the first optical sheet are three-dimensional serration structures with a cross-sectional view being serrations with sharp apexes.

6. The solar module package structure as claimed in claim 1, wherein the surface configurations of the first optical sheet are three-dimensional serration structures with a cross-sectional view being serrations with curved apexes.

7. The solar module package structure as claimed in claim 2, wherein the surface configurations of the first optical sheet are three-dimensional serration structures with a cross-sectional view being serrations with sharp apexes.

8. The solar module package structure as claimed in claim 2, wherein the surface configurations of the first optical sheet are three-dimensional serration structures with a cross-sectional view being serrations with curved apexes.

9. The solar module package structure as claimed in claim 2, wherein the surface configurations of the second optical sheet are three-dimensional serration structures with a cross-sectional view being serrations with sharp apexes.

10. The solar module package structure as claimed in claim 2, wherein the surface configurations of the second optical sheet are three-dimensional serration structures with a cross-sectional view being serrations with curved apexes.

11. A solar module package structure, comprising:
a back-plate;
a glass plate disposed above the back-plate;
a solar cell disposed between the glass plate and the back-plate;
an optical sheet disposed on the glass plate, wherein a light receiving surface of the optical sheet has surface configurations and is a front side surface, while an opposite surface of the first optical sheet facing the solar cell is a backside surface, and wherein the optical sheet has high front side transmittance and high backside reflection; and
an encapsulant disposed between the glass plate and the back-plate, fixing and encapsulating the solar cell.

12. The solar module package structure as claimed in claim 11, an index of refraction of the optical sheet is larger than that of air and smaller than that of the glass plate.

13. The solar module package structure as claimed in claim 11, wherein the surface configurations of the optical sheet are three-dimensional serration structures with a cross-sectional view being serrations with sharp apexes.

14. The solar module package structure as claimed in claim 11, wherein the surface configurations of the optical sheet are three-dimensional serration structures with a cross-sectional view being serrations with curved apexes.
